(19) United States
(12) Patent Application Publication
(10) Pub. No.: US 2013/0126711 A1
(43) Pub. Date: May 23, 2013

(54) LOW LIGHT VISION AND THERMAL IMAGING DEVICES WITH COOL CHIP COOLING

(71) Applicant: BOREALIS TECHNICAL LIMITED, London (GB)

(72) Inventors: Rodney T. Cox, North Plains, OR (US); Hans Walitzki, Portland, OR (US); Atniel Katan, Portland, OR (US); Isaiah W. Cox, Baltimore, MD (US)

(73) Assignee: BOREALIS TECHNICAL LIMITED, London (GB)

(21) Appl. No.: 13/680,157

(22) Filed: Nov. 19, 2012

Related U.S. Application Data
(60) Provisional application No. 61/561,048, filed on Nov. 17, 2011.

(51) Int. Cl. H01L 27/146

(52) U.S. Cl. CPC H01L 27/14601
USPC 250/208.1

(57) ABSTRACT

Improved low light vision and thermal imaging devices are provided. The devices of the present invention employ thermionic or thermotunneling cooling, with or without Avto Metals™, to ensure efficient operation under conditions of low illumination or the complete absence of illumination to detect emitted or reflected infrared and visible light radiation, significantly reducing thermal noise to produce superior image resolution and sensitivity within a small, lightweight footprint that will have a wide range of military, law enforcement, civilian, and other applications.

### PRIORITY CLAIM

This application claims priority from U.S. Provisional Application No. 61/561,048, filed Nov. 17, 2011, the disclosure of which is fully incorporated herein.

### TECHNICAL FIELD

The present invention relates generally to improvements in low light vision and thermal imaging devices and specifically to providing thermionic cooling for such devices.

### BACKGROUND OF THE INVENTION

Devices to enhance vision under low light conditions, known as night vision devices, and thermal imaging devices have long been available and relied on by the military and law enforcement agencies in the performance of their duties. These devices may be used alone or in combination to provide images to a viewer when there is very little environmental illumination or when it is completely dark and there is no ambient light. The technology for both low light vision and thermal imaging devices has improved significantly since each was first introduced, and these devices are capable of generating increasingly clearer images in a range of environments. Several generations of low light or night vision devices have been developed and named. The current generation, although not officially designated such, is commonly referred to as Gen-IV and includes an automatic gated power supply system that regulates photocathode voltage, allowing instantaneous adaptation to changing light conditions. The Gen-IV devices have a thin or removed ion barrier, which decreases the quantity of electrons usually rejected by the micro-channel plate positioned within the device, reducing image noise and permitting operation with a luminous sensitivity at 2,850 K of only 700. U.S. Pat. No. 6,911,652 to Walkenstein is illustrative of available low light imaging devices structured for use in a tactical environment where insufficient lighting is available and/or stealth is required. This type of device operates effectively at ambient temperatures to generate an image that is a combination of a thermal image and a photon based image.

It was discovered that the use of a cryogenically cooled focal plane array in a thermal imaging device, in which a photoelectrically responsive detector is cooled to a temperature in the cryogenic range, reduces unwanted thermal noise. Cooling the detector to cryogenic temperatures, below 0° C., allows an electrical response to invisible infrared light much deeper into the infrared part of the spectrum than was previously possible. A thermal imaging system with elements cooled as described produces vastly improved resolution and sensitivity. Cryogenically cooled systems are able to “see” a difference as small as 0.1° C. from more than 300 meters away. Providing the cryogenic cooling capability required to reduce thermal noise has presented challenges, however. The Dewar vessel initially used in this system required a supply of a cryogenic fluid, such as liquid nitrogen, that had to be provided and replenished by the user of a night vision or thermal imaging device cooled in this manner. Reverse Sterling-cycle coolers have been used more recently to develop cryogenic cooling, but these coolers are not only noisy, unreliable, and have maintenance problems, but the devices using them are very inefficient and require a strong power source.

The thermal imaging device described in U.S. Pat. No. 5,663,562 to Jones et al represents an improvement over the cryogenically cooled devices described above. To cool its detector to a sufficiently low temperature that thermally excited electrons do not cause an undesirably high level of electric noise that would hide the desired photoelectric image signal, the Jones et al device provides a Dewar vessel with a multistage reversed Peltier-effect, or thermoelectric, cooler. While the Jones et al device overcomes many disadvantages of cryogenically cooled thermal imaging devices, it is not suggested that the need for a Dewar vessel could be eliminated. Additionally, thermoelectric coolers are usually limited because of their inefficiency. Some manufacturers claim as high as a 10% of Carnot efficiency for thermoelectric coolers. In operation, however, efficiencies in the range of about 5% or less of Carnot appear to be more common. A 5% efficient device requires 20 watts of electrical power that must be disposed of to provide one watt of cooling. Thermoelectric coolers that can produce a large cooling effect, moreover, tend to be large, on the order of 1 cm², for example, and even larger with the packaging that is necessary to dispose of the large amount of heat generated by their operation. The size of these devices limits their usefulness in many low light vision and thermal imaging applications.

Cooling devices that overcome disadvantages of thermoelectric coolers are known. U.S. Pat. No. 5,955,772 to Shakouri et al, for example, discloses a heterostructure thermionic cooler intended to replace a thermoelectric cooler, primarily in integrated circuits. It is noted that the heterostructure thermionic device specifically described in this patent could be a single pixel or multiple pixels of a thermal imaging system. It is not suggested, however, that this heterostructure thermionic device could provide cooling for a low light vision device or for a thermal imaging device to produce superior resolution and sensitivity and/or to reduce thermal noise.

A need exists, therefore, for improved cooling in low light vision devices and thermal imaging devices that provides the increased resolution and sensitivity and reduced thermal noise advantages and benefits of cryogenically cooled devices within a smaller more lightweight footprint than is presently available.

### SUMMARY OF THE INVENTION

It is a primary object of the present invention to overcome the deficiencies of the prior art and to provide improved and effective cooling elements capable of producing increased resolution and sensitivity and reduced thermal noise in low light vision devices and thermal imaging devices.

It is another object of the present invention to provide thermionic cooling elements designed to effectively cool low light vision devices and thermal imaging devices, thereby enhancing images produced by these devices.

It is an additional object of the present invention to provide a thermionic or thermotunneling gap diode device capable of producing images in low light vision and thermal imaging devices with increased resolution and sensitivity and decreased thermal noise in the virtual absence of environmental illumination.

It is a further object of the present invention to provide improved low light vision and thermal imaging devices cooled by thermionic or thermotunneling means that are lighter, more efficient, and have a smaller footprint than previously available devices.

It is yet a further object of the present invention to provide improved low light vision and thermal imaging devices cooled by thermionic or thermotunneling means designed to function cooperatively with Avto Metals™ structures in the devices to achieve higher operating efficiencies than heretofore possible.

It is yet an additional object of the present invention to provide improved cooling in low light vision and thermal imaging devices practical for use in a wide range of military, civilian, law enforcement, and space applications.

In accordance with the aforesaid objects, improved low light vision and thermal imaging devices are provided. The devices of the present invention employ thermionic or thermotunneling cooling, with and without the use of Avto Metals™, to operate efficiently with minimal light or in the complete absence of environmental illumination produce superior resolution and sensitivity and significantly reduced thermal noise that are light in weight, have a decreased footprint, and are useful in a wide range of military, law enforcement, civilian, and other applications.

Other objects and advantages will be apparent from the following description, drawings, and claims.

### BRIEF DESCRIPTION OF THE DRAWINGS

FIG. 1 is a diagrammatic representation of one possible arrangement of functionally cooperating components of a generic low light vision device or thermal imaging device incorporating chip cooling in accordance with the present invention; and

FIG. 2 illustrates one embodiment of a thermionic or thermotunneling element useful for cooling the low light vision or thermal imaging device of FIG. 1.

### DESCRIPTION OF THE INVENTION

The improved low light vision and thermal imaging devices of the present invention achieve superior resolution, sensitivity, and noise reduction under extreme low light conditions as well as in the complete absence of environmental illumination. The devices of the present invention are capable of sensing radiation of wavelengths of 0.5 to 1.0 μm in the visible spectrum, as well as radiation in the near infrared spectrum and up to wavelengths of 10 μm in the far infrared spectrum and of providing effective cooling for their image sensors. The light weight and small footprint possible with the present devices contribute further to their desirability for use in cooling low light vision and thermal imaging devices that are intended to be used in a variety of tactical and stealth situations. Low light vision and thermal imaging devices in accordance with the present invention can be configured for effective use in a wide range of military, civilian, and law enforcement applications, although other applications are also contemplated to be within the scope of the present invention.

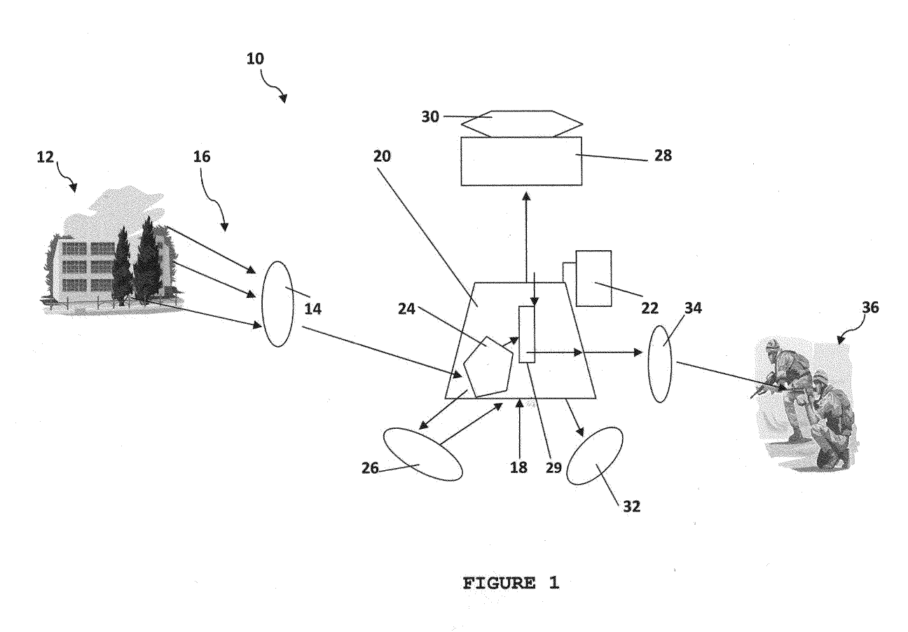

FIG. 1 illustrates one possible arrangement of basic components in a generic low light vision or thermal imaging device that incorporates chip cooling in accordance with the present invention to generate extremely clear visible images from infrared and visible light spectrum radiation under environmental conditions ranging from low to no light. The device of FIG. 1 is merely illustrative, and some devices may not include all of the components shown while others may include additional components. Some low light vision devices, for example, also include thermal imaging assemblies. Any low light vision device and/or thermal imaging device that senses images across the spectrum from visible light wavelengths (0.5 to 1.0 μm) through the far infrared wavelengths (up to 10 μm) and employs cooling to enhance image production is contemplated to fall within the scope of the present invention.

The device of FIG. 1 shows, in a diagrammatic representation, the main functionally cooperative components in one possible arrangement in a thermal imaging or low light vision device. These functionally cooperative components could additionally be arranged in any of a number of other convenient configurations or arrangements. Device 10 of FIG. 1 includes an objective optics element 14 that may include a group of lenses (not shown) that are transparent to light or radiation in the spectral band of interest, which may not necessarily include visible light, but, in this case, will include infrared, including near and far infrared, and visible light spectrum radiation. The objective optics element 14 will be pointed toward a scene 12 to be viewed. The scene 12 shown in FIG. 1 is a landscape, but this is not meant to be limiting. The devices of the present invention could be used to view any exterior or interior scene, whether on land, water, in the atmosphere, or in space. In addition to obtaining selected information about a scene, a scene could also be identified as a potential target by the present devices, and appropriate action could be taken in response to the target identification. Light, including visible light and infrared radiation, from the scene 12, indicated by arrows 16, is received and focused by optics element 14, concentrated and collimated, and directed into a chamber 18. The chamber 18 may contain a variety of different components, depending on the specific low light vision or thermal imaging device, but most of these devices include at least a scanner 20, operated by a source of power 22, and a fixed or rotatable, usually multi-faceted, scanning mirror 24 to reflect light received from the objective optics element 14 to an image optics element 26. In some applications, such as, for example, when a near infrared sensor (not shown) is one of the additional components included with the device, the optics element 26, or first amplifier, should also be cooled to enhance the images produced.

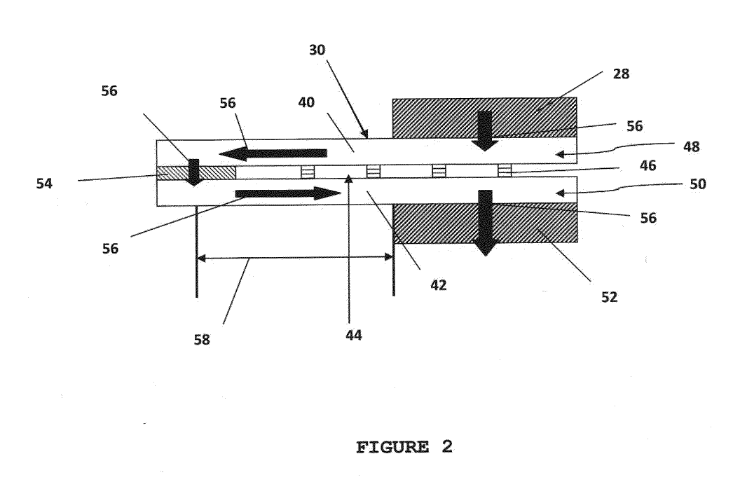

The image optics element 26 preferably includes mirrors (not shown) positioned to reflect light that originated with the scene to be viewed to a detector assembly 28 designed to detect infrared and/or visible light spectrum radiation and convert the detected radiation to electrical signals, which are transmitted ultimately to produce an image of the scene viewed. Detector assemblies that perform this function are known in the art, and it is contemplated that a range of detector assemblies could be suitable for this purpose. The detector assembly 28 must be cooled to a sufficiently low temperature that thermally excited electrons do not cause an undesirably high level of electrical noise and hide the desired photoelectric image signal. A thermionic and/or thermotunneling cooling assembly 30, described in detail below in connection with FIG. 2, provides superior cooling in accordance with the present invention. Cooling assemblies could also be provided for other components of the device when appropriate.

To provide a visible image to be viewed by a user of the low light vision and/or thermal imaging device 10, the device may include an assembly 32 that includes a projection element. Such projection elements are known in the art and may be configured in a number of different ways. A resolution element 29 is preferably provided within the chamber 18 that interacts with the detector 28 and the scanning mirror 24 to reflect light to an ocular lens element 34 and, ultimately, to provide an image with very sharp resolution to the eyes of a viewer or operator 36 using the device 10 to view the scene 12. Many variations of such resolution element structures are known and could be used in the present low light vision and thermal imaging device. Alternatively, an image of the scene 12 could be transmitted to a display monitor (not shown) for simultaneous viewing by a number of viewers.

While the viewer 36 shown in FIG. 1 and described above may be a human, the detected image may be transmitted instead to another device capable of taking appropriate action upon receipt of the image information without human interaction. Examples of this include a launched defensive missile equipped both with a device according to the present invention and with a guidance and projectile targeting system that permits both the detection of an incoming missile and the destruction of the incoming missile before it has deployed a live or a dummy warhead. If the incoming missile is detected after live and/or dummy warheads have been deployed, a missile with a device according to the present invention will be able to discern the difference between a live and a dummy warhead. Additionally, a missile with a device according to the present invention will be able to use this detected information to target and destroy live warheads in the air where the damage from their destruction would be minimal. Missiles equipped with the devices of the present invention will also be able to detect an air to air target, and/or to avoid an air to air missile or projectile. There are many other air to air, air to ground, and ground to air situations where the superior thermal imaging information provided by the devices of the present invention enable an enhanced situational awareness and, thus, improved performance, on the part of an operator of a system incorporating these devices to destroy a variety of incoming, fixed, or mobile offensive or defensive missiles and the like.

FIG. 2 illustrates a preferred cooling assembly 30 for use in low light vision and/or thermal imaging devices in accordance with the present invention. As indicated above, more than one cooling assembly 30 may be provided to enhance image production in some applications. In addition, the extent or degree of cooling required to produce a superior image may vary. For low light sensors that act in the visible portion of the spectrum (wavelengths of 0.5 to 1.0 μm), cooling that reduces electrical noise may be sufficient. This degree of cooling may also be adequate for the sensors commonly used in night vision systems that are effective in the near infrared portion of the spectrum. Near infrared sensors need an illumination source, light that is invisible because it is in the near infrared band, so that reflected light from a scene or an object of interest can be detected. An additional cooling assembly could be required in these kinds of devices. Sensors that detect emitted infrared light or radiation from people and their surrounding environment must be sensitive to far infrared radiation with wavelengths of up to 10 μm. In devices of this type, more sensitive and effective cooling is required than for the devices that operate in the visible light and near infrared regions. The lower the temperature of a device that operates in the far infrared region can be reduced, the better the images produced will be.

A cooling assembly that is particularly preferred for these purposes is a thermionic and/or thermotunneling converter or gap diode device and may further be a device that employs Avto Metals™ to reduce electron work function and increase tunneling current. The provision of a sufficiently low electron work function in a device of the present invention produces the efficiencies and sensitivities previously mentioned. The use of Avto Metals™ in the cooling assembly makes the achievement of a Carnot efficiency that exceeds 10% a possibility. Examples of suitable thermionic and thermotunneling devices are described in commonly owned U.S. Patent Application Publications Nos. US2007/00135055 to Walitzki and US2009/0223548 to Walitzki et al, the disclosures of which are incorporated herein by reference. Other thermionic and/or thermotunneling devices could also be used, with or without the electron work function reduction produced by Avto Metals™. Avto Metals™ and the reduction of electron work function and efficiencies achieved by devices formed of Avto Metals™ are described in commonly owned U.S. Pat. No. 6,117,344 to Cox et al; U.S. Pat. No. 6,281,514 to Tavkhelidze; U.S. Pat. No. 6,495,843 to Tavkhelidze; U.S. Pat. No. 6,531,703 to Tavkhelidze; and U.S. Pat. No. 7,074,498 to Tavkhelidze et al. The disclosures of the aforementioned patents are incorporated herein by reference.

The preferred cooling assembly 30 is constructed to increase cooling power by increasing tunneling and thermionic emission of electrons, particularly those electrons excited by photons of infrared light falling on the detector 28. One preferred cooling assembly 30 is a thermotunneling converter that includes a pair of facing electrodes 40 and 42 separated by a gap 44 that is preferably maintained at a distance on the order of 5-10 nm by a plurality of spacers 46. Other structures for maintaining the gap 44 at a constant distance are also known and could be used, such as, for example, the arrangement of protrusions described below. The spacers 46 are particularly effective for this purpose, however, and allow fabrication of the cooling assembly 30 at a much lower cost than using piezo-electric actuators and the like. One portion 48 of electrode 40 is in heat transfer contact with the detector 28 or an equivalent structure in the low light vision and/or thermal imaging device 10 that requires cooling. A similarly located portion 50 of electrode 42 is in heat transfer contact with a heat sink 52. A bond pad 54, preferably spaced as far apart as possible from portions 48 and 50 on respective electrodes 40 and 42, secures the electrodes together and minimizes thermal leakage. One preferred distance, designated by arrow 58, between the active area of the electrodes in contact with the detector 28 and the heat sink 52 and the bond pad 54, is on the order of 5 mm, which limits the thermal leakage through the bond pad. Other distances could also be effectively employed.

Arrows 56 indicate the direction of heat flow through the thermotunneling converter from the detector 28, through electrode 40, bond pad 54, and electrode 42 to heat sink 52. This heat flow path provides extremely effective cooling for the detector in low light vision and thermal imaging devices, especially when electrode surfaces are formed to benefit from electron work function reduction and increased electron tunneling and cooling capacity associated with the use of Avto Metals™.

The structure of the thermotunneling cooling assembly shown in FIG. 2 is characterized by reduced thermal flux, on the order of about 0.1 W/cm² when the temperature across the assembly is 50K. The relative dimensions of the spacers 46 can be selected to affect the thermal conductivity of the assembly. Conditions within the cooling assembly 30 can additionally be selected to maximize the cooling capacity. If, for example, electrodes 40 and 42 are formed of SiO₂, applying a voltage potential of about 5 V to each electrode produces an electrical field of about 5 MV/cm across the gap 44, thereby increasing tunneling current. The result is a device with a cooling capacity substantially in excess of 100 W/cm².

The electrodes 40 and 42 may be formed of materials other than quartz to produce a cooling assembly 30 with a cooling capacity that produces improved low light vision and thermal imaging devices. Suitable electrode materials could include, for example, silicon, sapphire, and/or silicon or sapphire supporting a layer of a material selected to increase tunneling and thermionic emissions of electrons, such as, for example, copper, silver, titanium, and/or other materials known to be useful for this purpose. The Avto Metals™ described in the commonly owned patents incorporated by reference above produce especially efficient thermionic devices that are able to work effectively at significantly lower temperatures than was previously thought possible. These materials are illustrative only and not intended to be limiting. Other materials useful for the described function are also intended to be included within the scope of the present invention.

The electrodes 40 and 42 have been described as separated by spacers 46 to maintain a gap 44 between them. Alternatively, facing surfaces of the electrodes could be configured to create a gap between the electrodes by forming protrusions on each facing surface. The distance of the gap is determined by the height and spacing of the protrusions. In addition to the patents noted above that describe Avto Metals™, commonly owned U.S. Patent Application Publication No. US2008/0224124 to Tavkhelidze, the disclosure of which is incorporated herein by reference, further describes the beneficial effects on electron behavior of forming protrusions on an electrode surface in a thermotunneling converter device such as cooling assembly 30. Electrodes in a cooling assembly 30, such as that described in connection with the present invention, can be custom designed using this geometry to provide efficient and sensitive cooling.

A cooling assembly 30 like that described above can readily be incorporated into even the smallest low light vision and/or thermal imaging device because of its very small size and light weight. The extremely effective cooling produced by electron tunneling, particularly when Avto metals are incorporated in the assembly, produces superior sensitivity and image resolution compared to available low light vision and thermal imaging devices and may be effectively used in a wide range of such devices. Illustrative examples of possible applications for the superior resolution achieved by usable and practicable device of the present invention include a wide range of military, law enforcement, civilian, and other applications. While improved low light or night vision goggles, binoculars, weapon sights, and the like will be common uses of the present invention with which the public is most familiar, defense and space applications are more likely to benefit from the improvements possible with the devices of the present invention. For example, thermionic or thermotunneling cooling, both alone and in conjunction with Avto Metals™, in low light and thermal imaging devices as described herein will be provide heretofore unknown efficiencies in missile defense systems, whether such systems are land or sea based, satellite or missile based, or in any other form. Thermally cooled imager devices of the present invention, as described herein, will also be able to provide sufficiently specific information that will enable users of the devices to spot incoming missiles before or after separation of dummy or decoy warheads.

While the present invention has been described with respect to a limited number of embodiments, those skilled in the art will appreciate numerous modifications and variations therefrom. It is intended that the appended claims cover all such modifications and variations as fall within the true spirit and scope of this present invention.

### INDUSTRIAL APPLICABILITY

The present invention will find its primary applicability in providing improved low light vision and thermal imaging devices useful in a wide range of military, civilian, law enforcement, and other applications where a light weight device with superior resolution and sensitivity is desired.

1. A device for producing a clear, high resolution image of objects of interest under conditions of minimal or no illumination from infrared and visible light spectrum radiation emitted or reflected by said objects of interest, wherein said device comprises detector means for detecting said radiation emitted or reflected by said objects of interest and thermionic cooling means in thermal contact with said detector means for reducing thermal noise and producing said clear, high resolution image of said objects of interest.

2. The device of claim 1, wherein said thermionic cooling means comprises thermotunneling converter means including at least a pair of spaced electrode means configured to transfer heat and separated by a gap, wherein one of said electrode means is in heat transfer relationship with said detector means and the other of said electrode means is in heat transfer relationship with a heat sink, whereby heat is transferred from said detector means to said heat sink to cool said detector means.

3. The device of claim 2, wherein said gap between said electrode means is maintained at a constant efficient heat transfer distance by spacer means.

4. The device of claim 2, wherein said gap between said electrode means is formed and maintained by a series of patterned protrusions in facing surfaces of said electrode means, whereby electron work function is reduced and electron tunneling efficiency is increased to improve the cooling efficiency of said device.

5. The device of claim 1, further comprising a plurality of optical element means for receiving said infrared and visible light spectrum radiation and transmitting the received infrared radiation to said detector means to produce said image and from said detector means to a viewer, whereby said objects of interest can be clearly viewed.

6. The device of claim 2, wherein said device is configured to detect radiation from said objects of interest in the absence of environmental illumination.

7. The device of claim 2, wherein said device is configured to detect radiation from said objects of interest in the presence of minimal ambient light.

8. The device of claim 2, wherein said electrode means are formed from silicon or Avto Metals™.

9. The device of claim 2, wherein said electrode means are secured by bond pad means selected to minimize thermal loss during heat transfer.

10. The device of claim 2, further comprising a plurality of optical element means for receiving said infrared and visible light spectrum radiation and transmitting the received infrared radiation to said detector means to produce said image and from said detector means to a viewer, whereby said objects of interest can be clearly viewed.

11. The device of claim 1, wherein said device is selected from the group consisting of goggles, binoculars, weapons sights, missile detection systems, and missile thermal management systems.

12. The device of claim 1, wherein said objects of interest comprise incoming missiles and said image of said objects of interest enables a user of said device to distinguish between live warheads and dummy warheads.

13. The device of claim 12, wherein said user of said device is a human or an intelligent object.

14. The device of claim 13, wherein said user is an intelligent object comprising a missile detection system.

15. The device of claim 1, wherein said objects of interest are located at a location selected from the group consisting of locations on the ground surface, in the water, under the water, in the air, and in outer space.

16. The device of claim 1, wherein said device is a missile thermal management system and the objects of interest comprise a target.

17. A method for providing to a viewer a clear, high resolution image of an object or objects of interest from infrared and visible light spectrum radiation emitted or reflected by said object or objects of interest, wherein said method comprises:
(a) providing a device capable of detecting infrared and visible light spectrum radiation emitted or reflected by said object or objects of interest and transforming said emitted or reflected radiation to a viewable image;
(b) directing said device at said object or objects of interest to receive said emitted or reflected infrared and visible light spectrum radiation;
(c) providing detector means in said device for detecting said received infrared and visible light spectrum radiation and translating said infrared and visible light spectrum radiation into a viewable image;
(d) providing cooling means for maintaining said detector means at a temperature required to substantially eliminate thermal noise produced by said detected radiation, thereby producing a high resolution image of said object or objects of interest; and
(e) transmitting said viewable, high resolution image to a viewer.

18. The method of claim 17, wherein said object or objects of interest comprise a target, said viewer comprises a missile, and when said viewable, high resolution image is transmitted to said viewer, said viewer responds to said image by taking appropriate action against said target.

19. The method of claim 18, wherein said viewer is capable of using said device to detect live from dummy warheads, to detect an air to air target, or to avoid an air to air projectile by computing at least a path, velocity, and mass of said projectile.

20. The method of claim 18, wherein said object or objects of interest are located at locations selected from the group consisting of locations on the ground surface, in the water, under the water, in the air, and in outer space.
